(19) United States
(12) Patent Application Publication
(10) Pub. No.: US 2015/0168990 A1
(43) Pub. Date: Jun. 18, 2015

(54) APPARATUS AND METHOD FOR GENERATING SINUSOIDAL WAVES, AND SYSTEM FOR DRIVING PIEZOELECTRIC ACTUATOR USING THE SAME

(71) Applicant: SAMSUNG ELECTRO-MECHANICS CO., LTD., Suwon-Si (KR)

(72) Inventors: Chan Woo PARK, Suwon-Si (KR); Joo Yul KO, Suwon-Si (KR)

(73) Assignee: SAMSUNG ELECTRO-MECHANICS CO., LTD., Suwon-Si (KR)

(21) Appl. No.: 14/248,023

(22) Filed: Apr. 8, 2014

(30) Foreign Application Priority Data
Dec. 17, 2013 (KR) 10 2013-0156989

(51) Int. Cl. G06F 1/02; H03M 1/00; H03M 1/12; H01L 41/04

(52) U.S. Cl. CPC G06F 1/022; H01L 41/042; H03M 1/001; H03M 1/1245

(57) ABSTRACT

An apparatus for generating sinusoidal waves may include a look-up table storage unit storing a look-up table including a plurality of sampling points determined based on a base frequency and a sampling frequency, a sinusoidal wave generation unit calculating an integer ratio of the target frequency to the base frequency and loading sampling points from the look-up table by reflecting the integer ratio, to generate a sinusoidal wave, a voltage step-up unit providing a stepped-up voltage to the sinusoidal wave generation unit, and a correction control unit sensing the stepped-up voltage from the voltage step-up unit and performing controlling so that the sampling points are corrected in the case that a level of the stepped-up voltage does not meet a predetermined requirement.

### CROSS-REFERENCE TO RELATED APPLICATION

This application claims the benefit of Korean Patent Application No. 10-2013-0156989 filed on Dec. 17, 2013, with the Korean Intellectual Property Office, the disclosure of which is incorporated herein by reference.

### BACKGROUND

The present disclosure relates to an apparatus and a method for generating sinusoidal waves, and a system for driving a piezoelectric actuator using the same.

As electronic device technology advances, various driving apparatuses are being developed for use therein, and signals having various wave forms are being used in such driving apparatuses.

In particular, in the case of haptic technology used in touch-based devices such as mobile terminals, it is important to precisely respond to user data inputs.

In the field of haptic technology, a piezoelectric actuator driven with signal having a sinusoidal waveform is used, and accordingly, it is necessary to generate the waveform of the sinusoidal wave with greater precision in order to drive the piezoelectric actuator precisely.

According to the technology for driving a piezoelectric actuator in the related art, in order to precisely generate a sinusoidal waveform, a look-up table storing high resolution digital values and a high resolution digital-to-analog converter are required.

According to the technology for driving a piezoelectric actuator in the related art, however, the size of a chip for generating a sinusoidal waveform is increased and the manufacturing costs are relatively high.

Moreover, according to the technology for driving a piezoelectric actuator in the related art in which a stepped-up voltage is used in generating a waveform, if the amplitude of a generated sinusoidal wave is higher than the level of the stepped-up voltage, clamping may occur in the output sinusoidal wave.

### SUMMARY

An exemplary embodiment in the present disclosure may provide an apparatus and a method for generating sinusoidal waves capable of generating sinusoidal waves with greater precision with no distortion by way of detecting a stepped-up voltage and correcting a sampling point to eliminate clamping in the case that the amplitude of the generated sinusoidal wave is higher than the stepped-up voltage, and a system for driving a piezoelectric actuator using the same.

According to an exemplary embodiment in the present disclosure, an apparatus for generating sinusoidal waves may include: a look-up table storage unit storing a look-up table including a plurality of sampling points determined based on a base frequency and a sampling frequency; a sinusoidal wave generation unit calculating an integer ratio of the target frequency to the base frequency and loading sampling points from the look-up table by reflecting the integer ratio, to generate a sinusoidal wave; a voltage step-up unit providing a stepped-up voltage to the sinusoidal wave generation unit; and a correction control unit sensing the stepped-up voltage from the voltage step-up unit and performing controlling so that the sampling points are corrected in the case that a level of the stepped-up voltage does not meet a predetermined requirement.

The sinusoidal wave generation unit, upon receiving a request for correcting the sampling points from the correction control unit, may correct digital values of the sampling points to regenerate a sinusoidal wave.

The sinusoidal wave generation unit may include a waveform-synthesizing unit, and upon receiving a digital value of the target frequency, loading sampling points corresponding thereto; and a digital-to-analog converter outputting analog values corresponding to the loaded sampling points.

The correction control unit may correct a sampling point corresponding to an amplitude of the sinusoidal wave so that it has a lower level than the level of the stepped-up voltage in the case that the level of the stepped-up voltage is lower than the amplitude of the sinusoidal wave.

The correction control unit may include: an analog-to-digital converter converting the stepped-up voltage into a digital value; and a sampling point adjustment unit calculating a ratio between the digital value of the stepped-up voltage and the amplitude of the sinusoidal wave to perform controlling so that the value of the ratio is applied to the sampling points if the digital value of the stepped-up voltage is lower than the amplitude of the sinusoidal wave.

According to an exemplary embodiment in the present disclosure, a method for generating sinusoidal waves may include: storing a look-up table storing a plurality of sampling points determined based on a base frequency and a sampling frequency; generating a sinusoidal wave by calculating an integer ratio of a target frequency to the base frequency to load sampling points from the look-up table by reflecting the integer ratio; and correcting a sampling point corresponding to an amplitude of the sinusoidal wave if the amplitude of the sinusoidal wave is higher than the level of a stepped-up voltage.

The generating of the sinusoidal wave may include loading every n^{th} sampling point from among the plurality of sampling points if the integer ratio is n, to generate the sinusoidal wave.

The method may further include: if the sampling point is corrected, regenerating a sinusoidal wave using the corrected sampling point.

The generating of the sinusoidal wave may be performed by a digital-to-analog converter that, upon receiving a digital value of the target frequency, outputs analog values corresponding to sampling points corresponding to the target frequency.

The correcting of the sampling point may include: calculating a ratio between the digital value of the stepped-up voltage and the amplitude of the sinusoidal wave in the case that the level of the stepped-up voltage is lower than the amplitude of the sinusoidal wave, and applying the value of the ratio between the digital value of the stepped-up voltage and the amplitude of the sinusoidal wave to the sampling points.

According to an exemplary embodiment in the present disclosure, a system for driving a piezoelectric actuator may include: a piezoelectric actuator operated by receiving a sinusoidal wave at both terminals thereof; and an apparatus for generating sinusoidal waves, the apparatus generating a sinusoidal wave by adjusting a sampling point so that it meets a predetermined amplitude requirement, to supply the sinusoidal wave to the piezoelectric actuator.

The apparatus for generating sinusoidal waves may include: a look-up table storage unit storing a look-up table including a plurality of sampling points determined based on a base frequency and a sampling frequency; a sinusoidal wave generation unit calculating an integer ratio of the target frequency to the base frequency and loading sampling points from the look-up table by reflecting the integer ratio, to generate a sinusoidal wave; a voltage step-up unit providing a stepped-up voltage to the sinusoidal wave generation unit; and a correction control unit sensing the stepped-up voltage from the voltage step-up unit and performing controlling so that the sampling points are corrected in the case that a level of the stepped-up voltage does not meet a predetermined requirement.

The sinusoidal wave generating unit may load every n^{th} sampling point from among the plurality of sampling points if the integer ratio is n, to generate the sinusoidal wave.

The sinusoidal wave generation unit, upon receiving a request for correcting the sampling points from the correction control unit, may correct the sampling point to regenerate a sinusoidal wave.

The sinusoidal wave generation unit may include a waveform-synthesizing unit, upon receiving a digital value of the target frequency, loading sampling points corresponding thereto; and a digital-to-analog converter outputting analog values corresponding to the loaded sampling points.

The correction control unit may correct a sampling point corresponding to amplitude of the sinusoidal wave so that it has a lower level than the level of the stepped-up voltage in the case that the level of the stepped-up voltage is lower than the amplitude of the sinusoidal wave.

The correction control unit may include: an analog-to-digital converter converting the stepped-up voltage into a digital value; and a sampling point adjustment unit calculating a ratio between the digital value of the stepped-up voltage and the amplitude of the sinusoidal wave to perform controlling so that the value of the ratio is applied to the sampling points if the digital value of the stepped-up voltage is lower than the amplitude of the sinusoidal wave.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a system for driving a piezoelectric actuator according to an exemplary embodiment of the present disclosure;

FIG. 2 is a block diagram illustrating an apparatus for generating sinusoidal waves according to an exemplary embodiment of the present disclosure;

FIG. 3 is a block diagram of an example of the sinusoidal wave generation unit of FIG. 2;

FIG. 4 is a block diagram of an example of the correction control unit shown in FIG. 2; and

FIG. 5 is a flowchart illustrating a method for generating sinusoidal waves according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

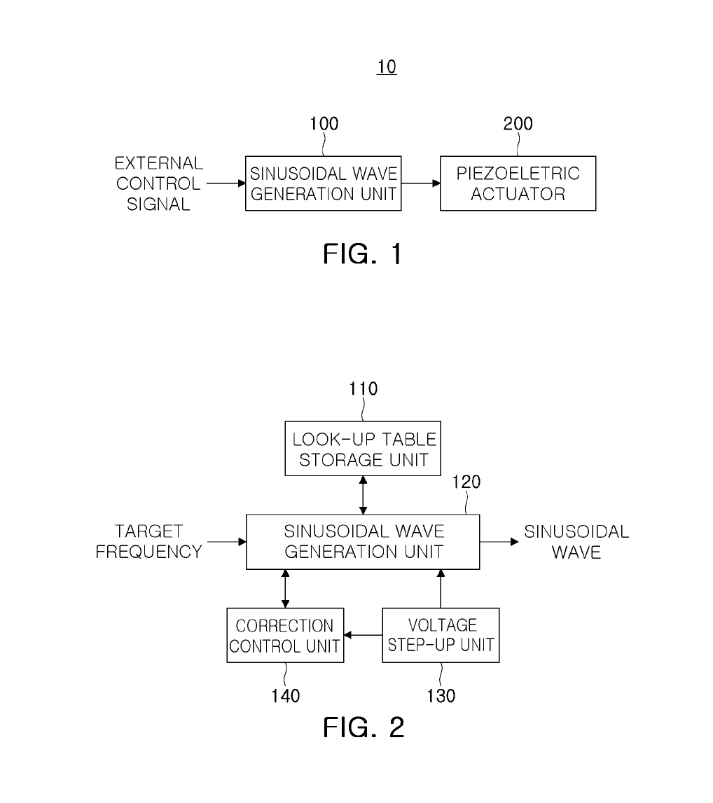

FIG. 1 is a block diagram of a system for driving a piezoelectric actuator according to an exemplary embodiment of the present disclosure.

The apparatus for generating sinusoidal waves 100 may generate sinusoidal waves to drive the piezoelectric actuator 200 and may provide it to the piezoelectric actuator 200. Accordingly, the apparatus for generating sinusoidal waves 100 may serve as an apparatus for driving the piezoelectric actuator 200.

Upon receiving an external control signal associated with sinusoidal waves to be generated (hereinafter, referred to as “target frequency”), the apparatus for generating sinusoidal waves 100 may generate a sinusoidal wave at the target frequency.

The apparatus for generating sinusoidal waves 100 may generate sinusoidal waves using a look-up table. The look-up table may include a plurality of sampling points determined based on a base frequency and a predetermined sampling frequency.

For example, if the base frequency is 7.8125 Hz and the predetermined sampling frequency is 8 KHz, there may be 1,024 sampling points. In this example, if the target frequency is 8 KHz, values corresponding to 1,024 sampling points are loaded, and analog values (e.g., current) corresponding to the values are output, thereby generating a sinusoidal wave.

That is, the apparatus for generating sinusoidal waves 100 may load the sampling points using the look-up table having digital values stored therein, and then perform digital-analog conversion to thereby generate a sinusoidal wave.

The apparatus for generating sinusoidal waves 100 may check if the generated sinusoidal wave meets a predetermined amplitude requirement, and, if not, may adjust the sampling frequency so as to regenerate a sinusoidal wave.

The piezoelectric actuator 200 may be operated by receiving at both terminals thereof the sinusoidal wave provided from the apparatus for generating sinusoidal waves 100.

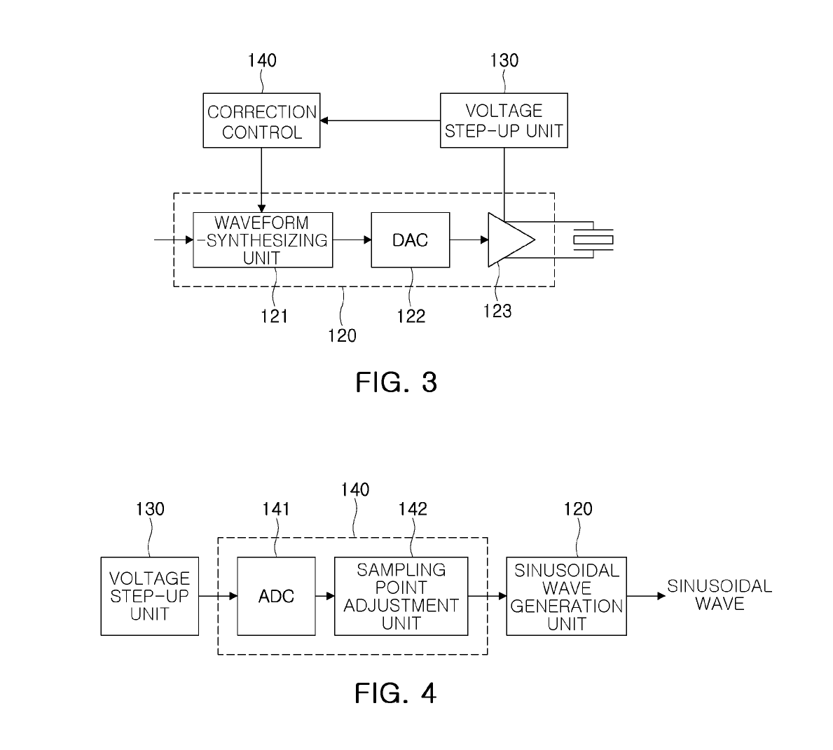

FIG. 2 is a block diagram of an apparatus for generating sinusoidal waves according to an exemplary embodiment of the present disclosure, FIG. 3 is a block diagram of an example of a sinusoidal generation unit shown in FIG. 2, and FIG. 4 is a block diagram of an example of a correction control unit shown in FIG. 2.

Hereinafter, apparatuses for generating sinusoidal waves according to various exemplary embodiments of the present disclosure will be described with reference to FIGS. 2 through 4.

Referring to FIG. 2, the apparatus for generating sinusoidal waves 100 may include a look-up table storage unit 110, a sinusoidal wave generation unit 120, a voltage step-up unit 130, and a correction control unit 140.

The look-up table storage unit 110 may store a look-up table that includes a plurality of sampling points determined based on a base frequency and a sampling frequency.

In an exemplary embodiment of the present disclosure, the look-up table may include 1,024 sampling points of the sampling frequency with respect to the base frequency.

The sinusoidal wave generation unit 120 may calculate an integer ratio of the target frequency to the base frequency and may load sampling points from the look-up table by reflecting the integer ratio, to generate a sinusoidal wave.

In an exemplary embodiment, the sinusoidal wave generation unit 120 may load every n^{th} sampling point from among the sampling points to generate a sinusoidal wave, where n denotes the integer ratio.

For example, let us assume that the reference frequency is 7.8125 Hz, the predetermined sampling frequency is 8 KHz, the target frequency is 23.4 KHz, and there are 1,024 sampling points. Since the value of the ratio of the target frequency to the base frequency is 3:1, the integer ratio is 3. Accordingly, the sinusoidal wave generation unit 120 may sample every third sampling point, e.g., 1st, 4th, 7th sampling point, and so on from among the 1,024 sampling points. Then, the sinusoidal wave generation unit 120 may output an analog value (e.g., current) corresponding to the retrieved sampling points, to generate a sinusoidal wave.

In an exemplary embodiment, upon receiving a request for correcting the sampling points from the correction control unit 140, the sinusoidal wave generation unit 120 may correct the frequency of the sampling points to regenerate a sinusoidal wave.

The voltage step-up unit 130 may provide a stepped-up voltage to the sinusoidal generation unit 120. That is, the voltage step-up unit 130 may receive a low voltage (e.g., 3 V to 5 V) supplied from an external voltage source and may step it up to a high voltage (e.g., 100 V) so as to supply the stepped-up voltage to the sinusoidal wave generation unit 120.

The correction control unit 140 may sense the stepped-up voltage from the voltage step-up unit 130 and may perform controlling so that sampling points are corrected in the case that the level of the stepped-up voltage does not meet a predetermined requirement.

In an exemplary embodiment, in the case that the level of the sensed, stepped-up voltage is lower than the amplitude of a sinusoidal wave generated from the sinusoidal wave generation unit 120, the correction control unit 140 may correct a sampling point corresponding to the amplitude of the sinusoidal wave so that it has a value that is equal to or lower than the level of the stepped-up voltage.

Referring to FIG. 3, the sinusoidal wave generation unit 120 may include a waveform-synthesizing unit 121, a digital-to-analog converter 122, and an amplifier 123.

Upon receiving a digital value for a target frequency, the waveform-synthesizing unit 121 may load sampling points corresponding thereto. The waveform-synthesizing unit 121 may receive sampling points corrected by the correction control unit 140 and may transmit it to the digital-to-analog converter 122.

The digital-to-analog converter 122 may output analog values corresponding to the sampling points loaded by the waveform-synthesizing unit 121.

The amplifier 123 may receive the stepped-up voltage from the voltage step-up unit 130 as its operation voltage and may filter the analog values output from the digital-to-analog converter 122 so as to generate a sinusoidal wave.

Referring to FIG. 4, the correction control unit 140 may include an analog-to-digital converter 141 and a sampling point adjustment unit 142.

The analog-to-digital converter 141 may sense the stepped-up voltage from the voltage step-up unit 130 and may convert it into a digital value.

The sampling point adjustment unit 142 may compare the stepped-up voltage, which has been converted into a digital value by the analog-to-digital converter 141, with a sampling point corresponding to the amplitude of a sinusoidal wave and may correct the sampling point if the digital value of the stepped-up voltage is lower than the sampling point.

If the stepped-up voltage is lower than the sampling points corresponding to the amplitude, the sampling point adjustment unit 142 may calculate the value of the ratio between the stepped-up voltage and the sampling points corresponding to the amplitude so as to apply it to the sampling points.

For example, if the stepped-up voltage is 80 V and the amplitude is 100 V, the value of the ratio between the stepped-up voltage and the amplitude is 0.8. The sampling point adjustment unit 142 may multiply the sampling points loaded by the waveform-synthesizing unit 121 by the calculated ratio, i.e., 0.8. By doing so, the amplitude of a sinusoidal wave generated by the amplifier 123 is limited within the range of the stepped-up voltage supplied to the amplifier 123, so that clamping does not occur.

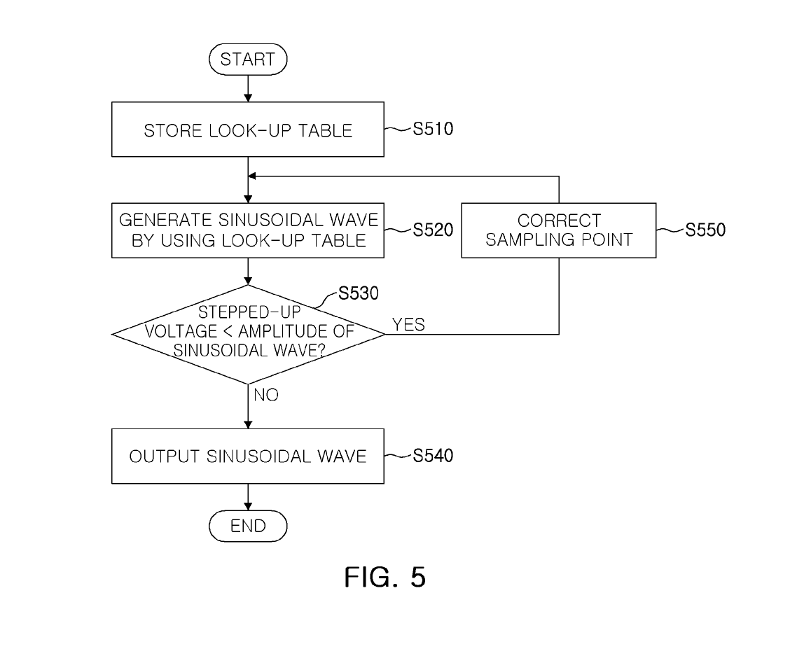

FIG. 5 is a flowchart illustrating a method for generating sinusoidal waves according to an exemplary embodiment of the present disclosure.

The method for generating sinusoidal waves according to the exemplary embodiment shown in FIG. 5 is performed by the apparatus for generating sinusoidal waves 100 described above with reference to FIGS. 1 through 4, and thus redundant descriptions will not be made.

Referring to FIG. 5, the apparatus for generating sinusoidal waves 100 may store a look-up table that includes a plurality of sampling points determined based on the base frequency and sampling frequency (S510).

Then, the apparatus for generating sinusoidal waves 100 may calculate an integer ratio of the target frequency to the base frequency and may load sampling points from the look-up table by reflecting the integer ratio, to generate a sinusoidal wave (S520).

If the amplitude of the sinusoidal wave is equal to or lower than the level of the stepped-up voltage provided in generating the sinusoidal wave (No in S530), the apparatus for generating sinusoidal waves 100 may output the generated sinusoidal wave (S540). If the amplitude of the sinusoidal wave is higher than the level of the stepped-up voltage provided in generating the sinusoidal wave (Yes in S530), the apparatus for generating sinusoidal waves 100 may correct the sampling points corresponding to the amplitude of the sinusoidal wave (S550).

In an exemplary embodiment, the look-up table may include 1,024 sampling points of the sampling frequency with respect to the base frequency.

In an example of operation 5520, assuming that the integer ratio is n, the apparatus for generating sinusoidal waves 100 may load every n^{th} sampling point from among the sampling points to generate a sinusoidal wave.

In an exemplary embodiment, when the sampling frequency is corrected, the apparatus for generating sinusoidal waves 100 may regenerate a sinusoidal wave using the corrected sampling frequency.

In an example of operation 5520, upon receiving a digital value for the target frequency, the apparatus for generating sinusoidal waves 100 may use a digital-to-analog converter that outputs analog values corresponding to the sampling points corresponding to the target frequency.

In an exemplary embodiment, the correcting of the digital value of the sampling points (S550) may include calculating the value of the ratio between the digital value of the stepped-up voltage and the amplitude of the sinusoidal wave in the case that the level of the stepped-up voltage is lower than the amplitude of the sinusoidal wave, and applying the value of the ratio between the digital value of the stepped-up voltage and the amplitude of the sinusoidal wave to the sampling points.

As set forth above, according to exemplary embodiments of the present disclosure, a sinusoidal wave can be generated more precisely with no distortion byway of detecting stepped-up voltage and correcting a sampling point if the amplitude of the generated sinusoidal wave is higher than the stepped-up voltage, thereby eliminating clamping.

While exemplary embodiments have been shown and described above, it will be apparent to those skilled in the art that modifications and variations could be made without departing from the spirit and scope of the present disclosure as defined by the appended claims.

What is claimed is:

1. An apparatus for generating sinusoidal waves, comprising:
a look-up table storage unit configured to store a look-up table including a plurality of sampling points determined based on a base frequency and a sampling frequency;
a sinusoidal wave generation unit configured to calculate an integer ratio of the target frequency to the base frequency and load sampling points from the look-up table by reflecting the integer ratio, to generate a sinusoidal wave;
a voltage step-up unit configured to provide a stepped-up voltage to the sinusoidal wave generation unit; and
a correction control unit configured to sense the stepped-up voltage from the voltage step-up unit and perform controlling so that the sampling points are corrected in the case that a level of the stepped-up voltage does not meet a predetermined requirement.

2. The apparatus of claim 1, wherein the sinusoidal wave generation unit, upon receiving a request for correcting the sampling points from the correction control unit, corrects digital values of the sampling points to regenerate a sinusoidal wave.

3. The apparatus of claim 1, wherein the sinusoidal wave generation unit includes:
a waveform-synthesizing unit, upon receiving a digital value for the target frequency, configured to load sampling points corresponding thereto; and
a digital-to-analog converter configured to output analog values corresponding to the loaded sampling points.

4. The apparatus of claim 1, wherein the correction control unit corrects a sampling point corresponding to an amplitude of the sinusoidal wave so that it has a lower level than the level of the stepped-up voltage in the case that the level of the stepped-up voltage is lower than the amplitude of the sinusoidal wave.

5. The apparatus of claim 1, wherein the correction control unit includes:
an analog-to-digital converter configured to convert the stepped-up voltage into a digital value; and
a sampling point adjustment unit configured to calculate a ratio between the digital value of the stepped-up voltage and the amplitude of the sinusoidal wave to perform controlling so that the value of the ratio is applied to the sampling points if the digital value of the stepped-up voltage is lower than the amplitude of the sinusoidal wave.

6. A method for generating sinusoidal waves, comprising:
storing a look-up table storing a plurality of sampling points determined based on a base frequency and a sampling frequency;
generating a sinusoidal wave by calculating an integer ratio of a target frequency to the base frequency to load sampling points from the look-up table by reflecting the integer ratio; and
correcting a sampling point corresponding to an amplitude of the sinusoidal wave if the amplitude of the sinusoidal wave is higher than the level of a stepped-up voltage.

7. The method of claim 6, wherein the generating of the sinusoidal wave includes loading every n′ sampling point from among the plurality of sampling points so as to generate the sinusoidal wave, where n denotes the integer ratio.

8. The method of claim 6, further comprising:
if the sampling point is corrected, regenerating a sinusoidal wave using the corrected sampling point.

9. The method of claim 6, wherein the generating of the sinusoidal wave is performed by a digital-to-analog converter that, upon receiving a digital value for the target frequency, outputs analog values corresponding to sampling points corresponding to the target frequency.

10. The method of claim 6, wherein the correcting of the sampling point includes:
calculating a ratio between the digital value of the stepped-up voltage and the amplitude of the sinusoidal wave in the case that the level of the stepped-up voltage is lower than the amplitude of the sinusoidal wave; and
applying the value of the ratio between the digital value of the stepped-up voltage and the amplitude of the sinusoidal wave to the sampling points.

11. A system for driving a piezoelectric actuator, comprising:
a piezoelectric actuator operated by receiving a sinusoidal wave at both terminals thereof; and
an apparatus for generating sinusoidal waves, the apparatus generating a sinusoidal wave by adjusting a sampling point so that it meets a predetermined amplitude requirement, to supply the sinusoidal wave to the piezoelectric actuator.

12. The system of claim 11, wherein the apparatus for generating sinusoidal waves includes:
a look-up table storage unit configured to store a look-up table including a plurality of sampling points determined based on a base frequency and a sampling frequency;
a sinusoidal wave generation unit configured to calculate an integer ratio of the target frequency to the base frequency and load sampling points from the look-up table by reflecting the integer ratio, to generate a sinusoidal wave;
a voltage step-up unit configured to provide a stepped-up voltage to the sinusoidal wave generation unit; and
a correction control unit configured to sense the stepped-up voltage from the voltage step-up unit and perform controlling so that the sampling points are corrected in the case that a level of the stepped-up voltage does not meet a predetermined requirement.

13. The system of claim 12, wherein the sinusoidal wave generation unit loads every n^{th} sampling point from among the plurality of sampling points so as to generate the sinusoidal wave, where n denotes the integer ratio.

14. The system of claim 12, wherein the sinusoidal wave generating unit, upon receiving a request for correcting a sampling point from the correction control unit, corrects the sampling point so as to regenerate a sinusoidal wave.

15. The system of claim 12, wherein the sinusoidal wave generation unit includes a waveform-synthesizing unit, upon receiving a digital value of the target frequency, configured to load sampling points corresponding thereto; and a digital-to-analog converter configured to output analog values corresponding to the loaded sampling points.

16. The system of claim 12, wherein the correction control unit corrects a sampling point corresponding to an amplitude of the sinusoidal wave so that it has a lower level than the level of the stepped-up voltage in the case that the level of the stepped-up voltage is lower than the amplitude of the sinusoidal wave.

17. The system of claim 12, wherein the correction control unit includes:
an analog-to-digital converter configured to convert the stepped-up voltage into a digital value; and
a sampling point adjustment unit configured to calculate a ratio between the digital value of the stepped-up voltage and the amplitude of the sinusoidal wave to perform controlling so that the value of the ratio is applied to the sampling points if the digital value of the stepped-up voltage is lower than the amplitude of the sinusoidal wave.
